(19) United States
(12) Patent Application Publication
(10) Pub. No.: US 2008/0284456 A1
(43) Pub. Date: Nov. 20, 2008

(54) Test Apparatus of Semiconductor Devices

(76) Inventor: SUNG MAN PANG, Gwangmyeong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/122,087

(22) Filed: May 16, 2008

(30) Foreign Application Priority Data
May 16, 2007 (KR) 10-2007-0047539

(51) Int. Cl. G01R 31/26

(52) U.S. Cl. 324/754; 324/765

(57) ABSTRACT

A test apparatus of a semiconductor device is provided. A signal pin can be electrically connected to a connector and can have a region for electrically connecting to a semiconductor device. The signal pin can be inserted into the connector, and the region of the signal pin for electrically connecting to a semiconductor device can be located on a portion of the signal pin that is not inserted into the connector.

### CROSS-REFERENCE TO RELATED APPLICATION

The present application claims the benefit under 35 U.S.C. §119 of Korean Patent Application No. 10-2007-0047539, filed May 16, 2007, which is hereby incorporated by reference in its entirety.

### BACKGROUND

After manufacture of a semiconductor device, testing is typically performed to verify electrical and operational characteristics of the device.

FIG. 1 shows a semiconductor device 20 in a wafer state connected to a typical test apparatus [FIG. 1(a)] and an equivalent circuit thereof [FIG. 1(b)].

Semiconductor devices are generally sorted into two categories according to position and orientation of electrodes. A horizontal-type device has a plurality of electrodes arranged on an upper surface of a substrate, and a vertical-type device has electrodes distributed on the upper and lower surfaces of the substrate. Vertical-type devices are often referred to as discrete-type devices.

A vertical-type semiconductor device, such as a diode, typically has at least two electrodes distributed on the upper and lower surfaces of the substrate. FIG. 1 shows a vertical-type semiconductor device installed on the test apparatus.

The vertical-type semiconductor device 20 is fixed to a wafer chuck 10 in a wafer state, wherein the lower electrodes of the semiconductor device 20 are electrically connected to the wafer chuck 10. A signal measuring apparatus 40 is connected to the wafer chuck 10 through a DC cable 32, and the DC cable 32 can be connected to probes 30 that can contact the upper electrodes of the semiconductor device 20.

An inspector can contact tips of the probes 30 to the electrodes on the wafer and can test signal characteristics by operating the signal measuring apparatus. However, this test method is typically only suitable for testing DC signals.

For the measurement of AC signals or high frequency characteristics of a semiconductor device, testing typically involves separating the semiconductor device into a chip unit.

FIG. 2 shows a typical equivalent circuit where semiconductor devices 21, 22, 23 are connected to a measuring apparatus.

An example of a two-terminal, vertical-type semiconductor device, is a diode, such as a signal processing diode, a light emitting diode for converting electric signals into optical signals, and a photodiode for converting optical signals into electric signals.

FIG. 2(a) shows a typical case of testing a signal processing diode 21; FIG. 2(b) shows a case of testing a light emitting diode 22; and FIG. 2(c) shows a case of testing a photodiode 23. The devices 21, 22, 23 are separated from a wafer state into a chip state and then connected to a bias-T circuit 50 for separating/coupling signals of an AC/DC component. The bias-T circuit 50 is connected to a signal input terminal 41 and a bias terminal 42 of the measuring apparatus.

Also, an electrode of the signal processing diode 21 is connected to a signal output terminal 43 of the measuring apparatus, while electrodes of the light emitting diode 22 and the photo diode 23 are grounded when performing tests for the AC signal or high frequency characteristics.

FIG. 3 is a view showing a first type of installation of a semiconductor device 120 on a test apparatus, and FIG. 4 is a view showing a second type of installation of a semiconductor device 120 on a test apparatus. FIG. 5 shows a test apparatus of a semiconductor device connected to a measuring apparatus.

Referring to FIG. 3, a lower electrode of the semiconductor device 120 is die-bonded to a bonding pattern 114 of a substrate 110, and an upper electrode of the semiconductor device 120 is wire-bonded to a separate bonding pattern 114.

Each bonding pattern 114 is bonded to a connection pin 112, and the connection pins 112 are connected to connectors 100. Therefore, the connectors 100 can be connected to both sides of the substrate 110.

For a second type of installation, the semiconductor device 120 is first bonded on a separate substrate. For example, referring to FIG. 4(a), connection pins 132, 134 are formed on a first substrate 130, and the semiconductor device 120 is die-bonded and wire-bonded to the first connection pins 132, 134, respectively. As shown in FIG. 4(b), the first connection pins 132, 134 of the first substrate 130 are then connected to the corresponding bonding patterns 114 of the second substrate 110.

The connection configuration of the bonding pattern 114, the second connection pin 112, and the connector 100 of the second substrate 110 has the same configuration as the first form explained in FIG. 3.

Referring to FIG. 5, a test apparatus with the mounted semiconductor device 120 (either in accordance with the first type of installation or the second type of installation) can be connected to the terminals 41, 42, 43 of a measuring apparatus, to perform testing.

However, the typical test apparatus requires many materials, such as a plurality of printed circuit boards formed with bonding patterns, connectors, connection pins, and bonding wires. Additionally, a plurality of processes are required, such as a chip carrier process, a wire bonding process, a connection pin bonding process, and a die bonding process, which can be time-consuming and can lead to high manufacturing costs.

Also, since each test apparatus for the typical chip-separated semiconductor devices needs to be manufactured, the efficiency of the test process is lowered.

Furthermore, due to the complex nature of the typical test apparatus, measurement of the inherent characteristics of the semiconductor device is limited, and the reliability of the measured data is degraded.

Thus, there exists a need in the art for an improved test apparatus of a semiconductor device.

### BRIEF SUMMARY

Embodiments of the present invention provide a test apparatus of a semiconductor device that can be manufactured easily and inexpensively. The test apparatus according to embodiments of the present invention can rapidly perform test operations and accurately measure the inherent characteristics of a semiconductor device. In certain embodiments, the semiconductor device under test is a chip-separated, vertical-type semiconductor device.

A test apparatus of a semiconductor device according to an embodiment of the present invention can comprise: a connector comprising a coupling part, a housing space, and an electric conducting part; a signal pin having a first portion inserted into the connector and electrically connected to the electric conducting part and a second portion for electrical connection to a semiconductor device.

### BRIEF DESCRIPTION OF THE DRAWINGS

FIG. 1 shows a semiconductor device in a wafer state on a typical test apparatus and an equivalent circuit thereof.

FIG. 2 shows an equivalent circuit of a semiconductor device connected to a typical measuring apparatus.

FIG. 3 shows a semiconductor device on a typical test apparatus.

FIG. 4 shows a semiconductor device on a typical test apparatus.

FIG. 5 shows a connection form of a typical test apparatus of a semiconductor device and a measuring apparatus.

FIG. 6 shows components of a test apparatus of a semiconductor device according to an embodiment of the present invention.

FIG. 7 shows a test apparatus of a semiconductor device according to an embodiment of the present invention.

FIG. 8 shows a test apparatus of a semiconductor device according to an embodiment of the present invention.

FIG. 9 shows a test apparatus of a semiconductor device according to an embodiment of the present invention.

FIG. 10 shows a test apparatus of a semiconductor device according to an embodiment of the present invention.

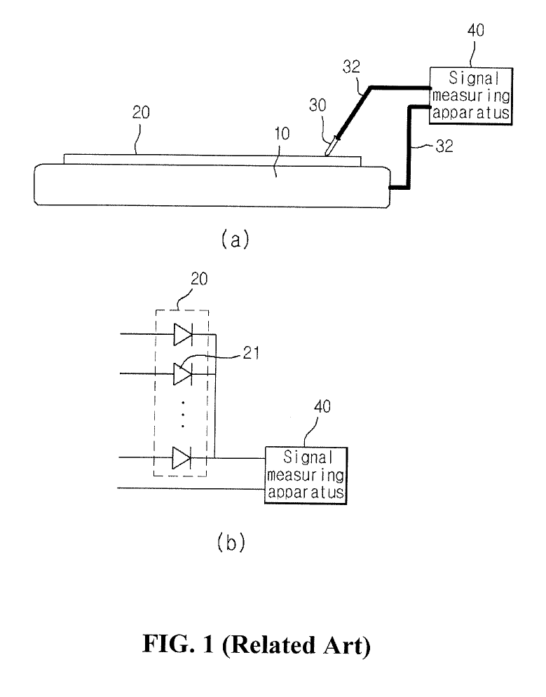

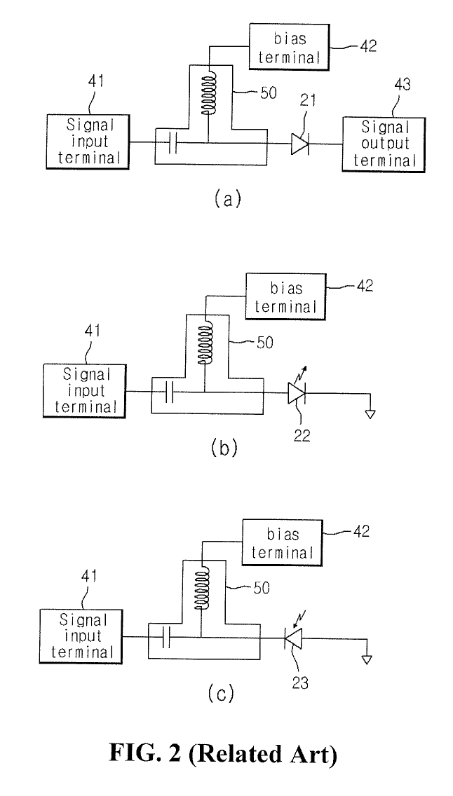

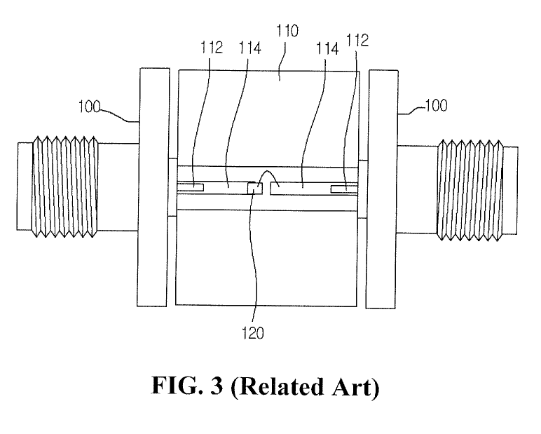

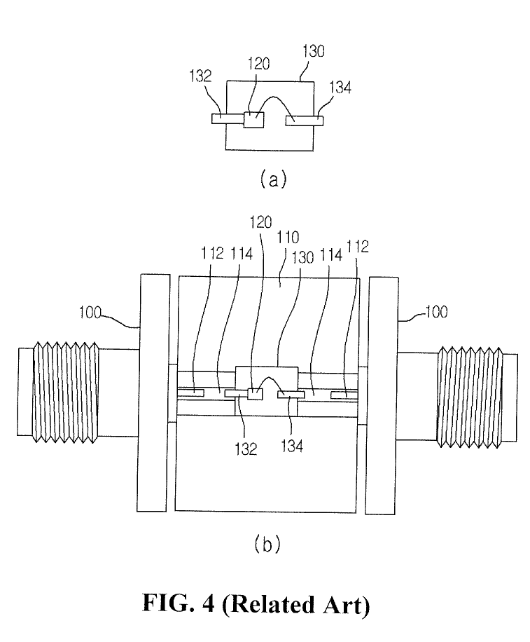

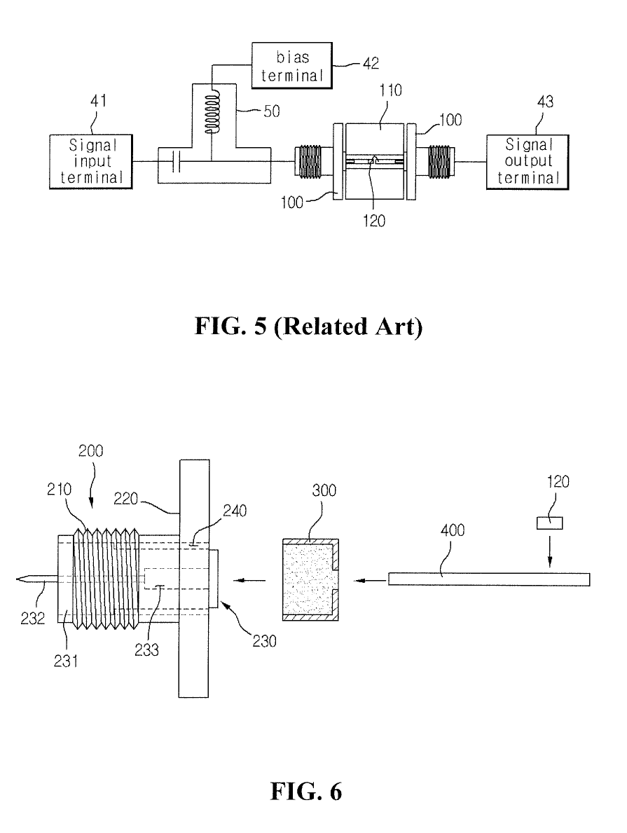

### DETAILED DESCRIPTION

FIG. 6 shows components of a test apparatus of a semiconductor device according to an embodiment of the present invention.

Referring to FIG. 6, a test apparatus of a semiconductor device, according to an embodiment of the present invention, can include: a connector comprising a connector main body 200; a supporting part 300; and a signal pin 400.

In one embodiment, the connector can be connected to a terminal of a measuring apparatus to transfer a signal supplied from the measuring apparatus to the signal pin 400.

The connector main body 200 can include a coupling part 210 and an electric conducting part 230, and the inside of the connector can be provided with a housing space 240.

The coupling part 210 can be implemented, for example, in the form of a female screw or a male screw. In one embodiment, the coupling part 210 can be detachably connected to a terminal of a measuring apparatus. In another embodiment, the coupling part 210 can be detachably connected to a terminal of a coupling separator.

The terminal of the measuring apparatus or the terminal of the coupling separator can also have a screw form corresponding to the coupling part 210.

The electric conducting part 230 can be provided inside the connector main body 200 and can be electrically insulated from the connector main body 200 using an insulating material 231. The electric conducting part 230 can comprise a conducting material 232, such as copper, in a metal line form. The electric conducting part can have an aperture 233 to allow insertion of the signal pin 400 and contact of the signal pin 400 with the conducting material 232.

The housing space 240 can be provided on an inside portion of the connector, including an inside portion of the electrical conducting part 230. In one embodiment, the housing space 240 can be wide enough to receive a supporting part 300.

The supporting part 300 can be a cylindrical bead with a through hole formed therein and can be inserted into the housing space 240. The signal pin 400 can be inserted into the through hole of the supporting part 300 and the aperture 233 of the electric conducting part 230.

When the signal pin 400 is inserted into the through hole of the supporting part 300, the supporting part 300 can be in the connector main body 200 such that the signal pin 400 is inserted into the aperture 233 of the electric conducting part 230 and electrically connected to the conducting material 232 of the electric conducting part 230.

In an embodiment, the connector main body 200 can include a fixing part 220 to fix the test apparatus to a structure. The structure can be any suitable structure known in the art, such as a jig.

The fixing part 220 can be fixed to the structure through any suitable connection means known in the art. In one embodiment, the fixing part 220 can be fixed to a jig by a projection or a clip of the jig by forming a hole on a surface projected from the outside of the connector main body 200.

The connector can be implemented in any suitable connector form known in the art. For example, the connector can be implemented in a Sub-Miniature A (SMA) connector form or a connector form for high frequency like a terminal of oscilloscope and high-frequency cable connector.

A portion of the signal pin 400 can be connected to the connector main body 200, and a portion of the signal pin 400 exposed to the outside of the connector main body 200 can be mounted with the semiconductor device 120. The semiconductor device 120 can be separated in a chip state.

In one embodiment, the mounting portion of the semiconductor device 120 adjacent to the signal pin 400 has a plate form.

In an embodiment, the signal pin 400 can be a plate form of a metal material, thinly and lengthily formed as a whole.

The signal pin 400 can be detachably connected to the connector main body 200 through the supporting part 300. For example, the signal pin 400 can be detachably connected to the connector main body 200 such that it is inserted or removed the through hole of the supporting part 300.

In one embodiment, the test apparatus of the present invention can by applied to vertical-type semiconductor devices having electrodes on the upper and lower surfaces thereof. The vertical-type semiconductor device can be, for example, a photodiode, a light emitting diode, a signal processing diode, or a transistor.

The semiconductor device 120 can be electrically connected to a portion of the signal pin 400 exposed to the outside of the connector main body 200. For example, the semiconductor device 120 can be connected to the signal pin in a direct die-bonded scheme.

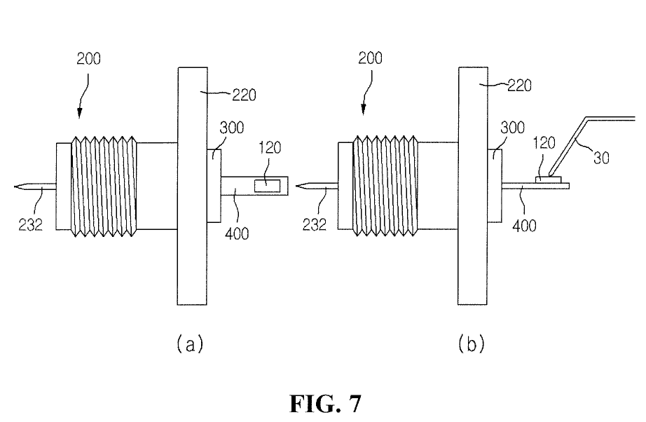

FIG. 7 shows a test apparatus of a semiconductor device according to an embodiment of the present invention.

FIG. 7 (a) shows a top view of a test apparatus with the signal pin 400 inserted into the connector main body 200, and FIG. 7(b) shows a side view of a test apparatus with the signal pin 400 inserted into the connector main body 200.

Referring to FIG. 7, the connector main body 200, the supporting part 300, the signal pin 400, the semiconductor device 120 can be connected, and the connector can be connected to a measuring apparatus or a coupling separator. Thus, an inspector can conveniently and rapidly perform test operations by contacting a probe of the measuring apparatus to an upper electrode of the semiconductor device 120.

In one embodiment, the connector connected to the measuring apparatus or the coupling separator can be fixed to structure through the fixing part 220. The structure can be a testing table, such as a jig.

In an embodiment, the signal pin 400 can be bonded to the semiconductor device 120. Thus, when a testing of a semiconductor device 120 is completed, the signal pin 400 bonded to the semiconductor device can be removed from the connector main body 200. Then, another semiconductor device 120 bonded to a different signal pin 400 can be inserted into the connector main body 200 for testing. This configuration allows for efficient testing of a large number of semiconductor devices.

When using the test apparatus of embodiments of the present invention, many components of a related art test apparatus, such as the plurality of printed circuit boards, connectors, bonding wires, and connection pins are not necessary. Also, the connector of the present invention can be repeatedly used.

Therefore, many of the consumable parts required in related art testing of semiconductor devices can omitted, allowing for a decrease in the manufacturing time and cost.

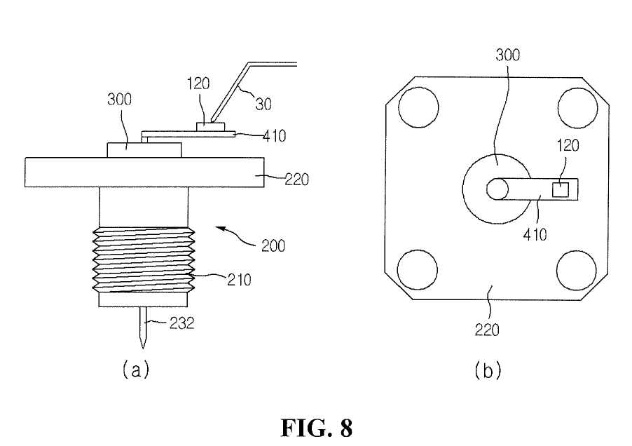

FIG. 8 shows a test apparatus of a semiconductor device according to an embodiment of the present invention.

Referring to FIG. 8, in an embodiment, the portion of the signal pin 410 exposed to the outside of the connector main body 200 can be bent. Although a signal pin 410 is shown in FIG. 8 bent at a right angle, embodiments of the present invention are not limited thereto. Any suitable angle of bending could be used for the signal pin 410.

In embodiments with the connector main body 200 fixed to a structure, the work environment can sometimes make it inconvenient to work with a straight signal pin. Thus, in one embodiment, the portion of the signal pin 410 exposed to the outside of the connector main body 200 can be bent, making it possible to perform the testing more smoothly.

In a specific embodiment, the semiconductor device 120 can be a vertical-type semiconductor device 120 with three or more electrodes. In such a semiconductor device 120, a lower electrode can be electrically connected with the signal pin 410. Then, an inspector can contact a probe or probes 30 with upper electrodes of the semiconductor device 120.

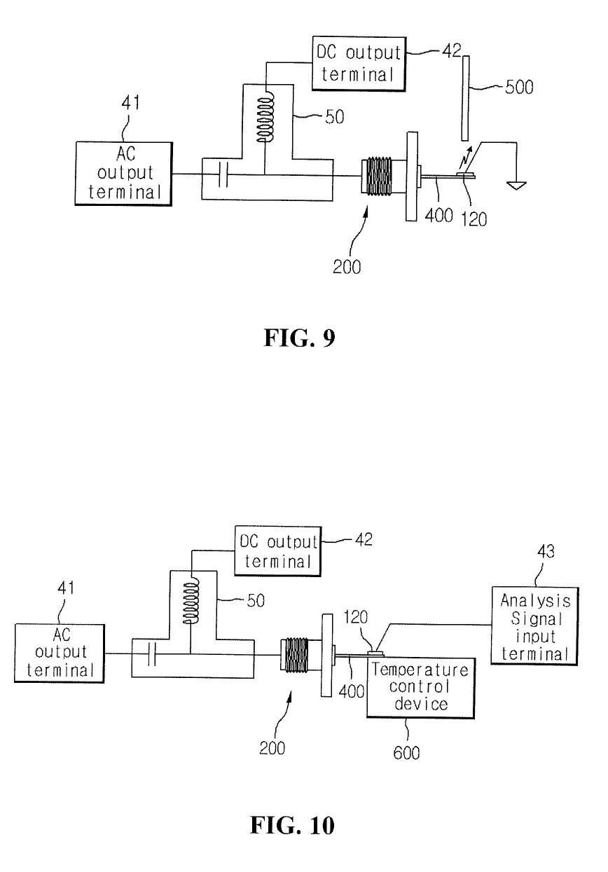

FIG. 9 shows a test apparatus of a semiconductor device according to an embodiment of the present invention.

Referring to FIG. 9, the test apparatus of the semiconductor device can be connected to a measuring apparatus through a coupling separator 50. The connector main body 200 can be connected to a terminal of the coupling separator 50, and the coupling separator 50 can be connected to a signal measuring apparatus.

As described above, a terminal of the coupling separator 50 can have a connection in the form of a female screw and a male screw corresponding to the coupling part 210 of the connector.

The coupling separator 50 can couple or separate an AC or RF component of a signal to or from a DC component of a signal to transfer it to the electric conducting part 230 of the connector main body 200. The coupling separator 50 can include a signal input terminal, a signal output terminal, and a bias terminal.

In one embodiment, the signal input terminal can be connected to an AC output terminal 41 of the measuring apparatus, such as a pulse generator, to receive the AC or RF component of a signal and transfer it to the electric conducting part 230. The RF component of the signal can have a bandwidth of from several Hz to several GHz.

Also, the bias terminal can be connected to a DC output terminal 42 of a DC voltage generator to receive the DC component of a signal, and the signal output terminal can be connected to the connector main body 200.

In one embodiment, the coupling separator 50 can include passive devices, such as an inductor and a capacitor, and can be implemented in a T-type housing with a signal input terminal, a signal output terminal, and a bias terminal.

In one embodiment, the semiconductor device 120 can be a signal processing diode, and the upper electrode can be electrically connected with a probe connected to a signal analysis apparatus. The signal analysis apparatus can be, for example, a spectrum analyzer or an oscilloscope.

In another embodiment, the semiconductor device 120 can be a photoelectric converter, and an upper electrode can be connected to a ground terminal.

In yet another embodiment, the semiconductor device 120 can be a light emitting diode (LED), and an upper electrode can be connected to a ground terminal, and a light measuring apparatus 500 for measuring emitted light can be installed on the semiconductor device 120.

The light measuring apparatus 500 can be implemented, for example, using a photodiode, a phototransistor, a CdS (Sulfuric Cadmium) cell, or a charge-coupled device (CCD).

Therefore, various signal characteristics and electrical characteristics can be analyzed using a test apparatus according to embodiments of the present invention. Depending on the type of semiconductor device to be tested, optical characteristics can also be analyzed.

FIG. 10 shows a test apparatus of a semiconductor device according to an embodiment of the present invention.

Referring to FIG. 10, in one embodiment, an upper electrode of the semiconductor device 120 can be connected to an analysis signal input terminal 43 of a signal analysis apparatus, and a temperature control device 600 is connected to a signal pin 400.

The temperature control device 600 can be, for example, a small chip device such as a thermal electric cooler (TEC). In an embodiment, the temperature control device 600 can be bonded to the signal pin 400. The semiconductor device 120 can be bonded to an opposite surface of the signal pin 400 from the temperature control device 600.

In another embodiment, the temperature control device 600 can be a passive device type circuit, which may be difficult to attach to the signal pin 400. Thus, the temperature control device 600 and the signal pin 400 can be connected through a heat conduction member.

The use of the temperature control device 600 allows accurate signal analysis and maintenance of optimum temperature even if the semiconductor device 210 is a high output device that produces large amounts of heat.

Additionally, the operation characteristics of the semiconductor device 120 can be tested under various temperature environments by controlling the temperature control device 600. Thus, a further apparatus such as a temperature chamber is not needed, making it possible to improve work efficiency.

The test apparatus of the semiconductor device according to embodiments of the present invention can be manufactured using many less components than a related art test apparatus. This makes it possible to reduce the manufacturing cost and time and to efficiently perform the test process.

In addition, the semiconductor device does not have to be packaged on a substrate, and signal terminals do not have to connect to the connectors, and the signal pin can be straight or at an angle, making it possible to easily and efficiently perform the testing operations.

Also, the signal pin connected to the semiconductor device can be inserted and extracted into and from the connector to rapidly perform testing processes, allowing testing of many semiconductor devices in a short time.

Furthermore, the many components of a related art test apparatus are not present, thereby inhibiting the effect of electrical noise on the signal. This improves the accuracy of the testing measurements of the inherent characteristics of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A test apparatus of a semiconductor device, comprising:
a connector comprising a coupling part, a housing space, and an electric conducting part; and
a signal pin comprising a first end and a second end, wherein a first portion of the signal pin is inserted into the housing space of the connector and detachably connected to the connector, and wherein the first end is electrically connected to the electric conducting part of the connector, and wherein a second portion of the signal pin is not inserted into the housing space of the connector and has a region for electrically connecting to a semiconductor device.

2. The test apparatus according to claim 1, wherein the connector further comprises a supporting part in the housing space, and wherein the signal pin is supported by the supporting member.

3. The test apparatus according to claim 2, wherein the supporting member is a cylindrical bead comprising a through hole formed therein.

4. The test apparatus according to claim 3, wherein the signal pin is inserted through the through hole of the supporting member.

5. The test apparatus according to claim 1, further comprising a semiconductor device electrically connected to the second portion of the signal pin.

6. The test apparatus according to claim 5, wherein the semiconductor device has a vertical-type structure having at least one electrode formed on an upper surface of the semiconductor device and at least one electrode formed on a lower surface of the semiconductor device.

7. The test apparatus according to claim 6, wherein the at least one lower electrode is bonded to the signal pin.

8. The test apparatus according to claim 1, wherein the connector further comprises a fixing part for fixing the connector to a structure.

9. The test apparatus according to claim 1, wherein the coupling part comprises a male screw or a female screw.

10. The test apparatus according to claim 1, wherein the coupling part is detachably connected to a terminal of a measuring apparatus.

11. The test apparatus according to claim 1, wherein the coupling part is detachably connected to a terminal of a coupling separator.

12. The test apparatus according to claim 11, wherein the coupling separator comprises a signal input terminal, a signal output terminal, and a bias terminal, and wherein the signal input terminal is connected to a signal generator, and wherein the signal output terminal is detachably connected to the coupling part.

13. The test apparatus according to claim 1, further comprising a semiconductor device bonded to the signal pin.

14. The test apparatus according to claim 13, wherein at least a portion of the second portion of the signal pin has a plate form, and wherein the semiconductor device is die-bonded to the signal pin.

15. The test apparatus according to claim 1, wherein the signal pin is straight.

16. The test apparatus according to claim 1, wherein the signal pin is bent at an angle.

17. The test apparatus according to claim 1, further comprising a temperature control device electrically connected to a third portion of the signal pin that is not inserted into the housing space of the connector.

18. The test apparatus according to claim 17, wherein the temperature control device is bonded to the signal pin.

19. The test apparatus according to claim 18, further comprising a semiconductor device, wherein the semiconductor device is bonded to an opposite surface of the signal pin from the temperature control device.

20. The test apparatus according to claim 17, wherein the temperature control device is electrically connected to the signal pin through a heat conduction member.
